(19) United States
(12) Patent Application Publication
(10) Pub. No.: US 2025/0207870 A1
(43) Pub. Date: Jun. 26, 2025

(54) WATER-COOLING PLATE AND MANUFACTURING METHOD OF WATER-COOLING PLATE SEAT

(71) Applicant: Ming-Hung CHEN, New Taipei City (TW)

(72) Inventor: Ming-Hung CHEN, New Taipei City (TW)

(21) Appl. No.: 18/395,480

(22) Filed: Dec. 23, 2023

(51) Int. Cl. F28F 3/04

(52) U.S. Cl. CPC F28F 3/04; F28F 2230/00; F28F 2255/00; F28F 2275/20

(57) ABSTRACT

A water-cooling plate and a manufacturing method of a water-cooling plate seat are disclosed. The manufacturing method includes a preparing step, a planing step and a forming step. The preparing step is to provide a substrate, the substrate has a top surface and a bottom surface. The planing step is to process a planing operation to make fins protruding from the top surface of the substrate. The forming step is to provide a top mold and a bottom mold, the top mold is engaged with the bottom mold to make the substrate be bent to form a surrounding wall protruding out of the top surface and surrounding the fins. Accordingly, the seat is formed in one piece to make the thermal resistance be reduced, and subsequent processes and the assembly or disassembly are facilitated.

### BACKGROUND OF THE DISCLOSURE

### Technical Field

The present disclosure relates to a water-cooling heat dissipating field, especially to a water-cooling plate and a manufacturing method of a water-cooling plate seat.

### Description of Related Art

A related-art water-cooling plate is commonly used in the water-cooling heat dissipating field. The water-cooling plate mainly includes a housing and a plurality of heat dissipating fins. The housing is sealed and has a chamber. Each of the heat dissipating fins are parallelly arranged in the chamber to allow a working fluid (for example water or a cooling fluid) to flow through. When the working fluid flows through each of the heat dissipating fins, heat contained in the working fluid is transferred to each of the heat dissipating fins to perform a heat dissipating operation, thus the temperature of the working fluid is efficiently lowered to achieve a heat dissipating effect.

Wherein, the housing has to be sealed and the plurality of the heat dissipating fins are disposed in the chamber, thus the related-art housing is designed in a two-piece or a multiple-piece manner to be easily manufactured. The plurality of heat dissipating fins are firstly soldered and fastened on one of the housings, and then each of the housings are assembled and soldered to form the water-cooling plate.

However, no matter the plurality of heat dissipating fins being soldered and fastened on the housing or each of the housings is soldered and fastened, a soldering material or a flux is required during the soldering operation, because the soldering material and the flux are made of different materials, and the above two and the housing and the heat dissipating fins are also made of different materials, thus the thermal resistance at each soldered location of the water-cooling plate is increased, and the heat dissipating efficiency of the water-cooling plate is affected.

Accordingly, the applicant of the present disclosure has devoted himself for improving the mentioned shortages.

### SUMMARY OF THE DISCLOSURE

The present disclosure is to make a water-cooling plate seat be formed in one piece form to reduce the thermal resistance, and facilitate subsequent processes and the assembly or disassembly.

Accordingly, the present disclosure provides a manufacturing method of a water-cooling plate seat, which includes a preparing step, a planing step and a forming step. The preparing step is to provide a substrate, the substrate has a top surface and a bottom surface opposite to the top surface. The planing step is to process a planing operation to make a plurality of fins be formed on the substrate, each of the fins protrudes from the top surface and parallelly arranged. The forming step is to provide a top mold and a bottom mold, the top mold is engaged with the bottom mold to make the substrate be bent to form a surrounding wall, and the surrounding wall protrudes out of the top surface and surrounds each of the fins.

According to one embodiment of the present invention, in the preparing step, the top surface of the substrate has a groove, the planing step is to use a planing process to make each of fins be sequentially formed on the top surface from one side of the groove.

According to one embodiment of the present invention, after each of the fins is formed, the top surface of the substrate is milled to be aligned with a bottom surface of the groove, and then the forming step is performed.

According to one embodiment of the present invention, in the preparing step, the substrate has a protrusion located on the top surface, the planing step is to process a planing operation to be protrusion to make each of the fins be formed.

According to one embodiment of the present invention, an aligning step is further included between the planing step and the forming step, the aligning step is to provide a top mold and a bottom mold, the top mold has a top recess and a top supporting part surrounding the top recess, the bottom mold has a bottom recess and a bottom supporting part surrounding the bottom recess, the top supporting part abuts against the top surface to make each of the fins be accommodated in the top recess, the bottom supporting part abuts against the bottom surface to make the top mold be arranged corresponding to the bottom recess.

According to one embodiment of the present invention, a screw thread processing step is further included, after the forming step, an inner screw thread is formed at an inner side of the surrounding wall.

According to one embodiment of the present invention, in the forming step, the substrate is bent to form a combination plate and a bottom plate, the groove and each of the fins are located on the bottom plate, and the surrounding wall is connected between the combination wall and the bottom plate.

According to one embodiment of the present invention, a screw hole processing step is further included, after the forming step, the combination plate is processed to be formed with a plurality of screw holes.

According to one embodiment of the present invention, a penetrated hole processing step is further included, after the forming step, the combination plate is processed to be formed with a plurality of penetrated holes.

Accordingly, the present disclosure provides a water-cooling plate, which includes a seat and a top cover which are formed in one piece. The seat includes a surrounding wall, a bottom plate and a plurality of fins. The bottom plate is processed with a planing operation to form each of the fins. The bottom plate is processed with a forming operation to be bent to form a surrounding wall, the surrounding wall surrounds and protrudes out of each of the fins. The top cover is correspondingly combined and fastened with the seat and a chamber is formed by the top cover and the seat, and each of the fins is accommodated in the chamber.

According to one embodiment of the present discourse, the surrounding wall has an inner screw thread, the top cover has an outer screw thread, and the outer screw thread is correspondingly screwed with the inner screw thread.

According to one embodiment of the present discourse, a plurality of screw bolts are included, the substrate is bent to form a combination plate. The surrounding wall is connected between the combination plate and the bottom plate, and each of the screw bolts passes one of the top cover and the combination wall and then be alternatively screwed with one of the combination wall and the top cover.

According to one embodiment of the present discourse, a rubber ring is further included, the top cover has a combination part, and the rubber ring is sheathed at the combination part and elastically clamped between the top cover and the seat.

Advantages achieved by the present disclosure are as follows. According to the manufacturing method of the water-cooling plate seat of the present disclosure, the plurality of fins are directly formed on the substrate in the planing step. The soldering operation requiring the soldering material or the flux is avoided, thus a problem of increasing the thermal resistance is prevented. The substrate is bent to form the surrounding wall in the forming step to facilitate the subsequent processes and the assembly or disassembly with the top cover, and avoid using the soldering material or the flux for the soldering operation to prevent the problem of increasing the thermal resistance.

According to the water-cooling plate of the present disclosure, each of the fins, the surrounding wall and the seat are formed in one piece, the top cover and the seat are correspondingly combined and fastened, thus the soldering material or the flux required by the soldering operation are saved, and the problem of increasing the thermal resistance is prevented.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a flowchart showing the steps according to the present disclosure;

FIG. 2 is a perspective view showing the substrate while the preparing step being processed according to the present disclosure;

FIG. 3 is a side cross sectional view showing the substrate while the preparing step being processed according to the present disclosure;

FIG. 4 is a side cross sectional view showing the substrate after the planing step being processed according to the present disclosure;

FIG. 5 is a side cross sectional view while the aligning step being processed according to the present disclosure;

FIG. 6 is a side cross sectional view while the forming step being processed according to the present disclosure;

FIG. 7 is a side cross sectional view after the forming step being processed according to the present disclosure;

FIG. 8 is a side cross sectional view after the screw thread processing step being processed according to the present disclosure;

FIG. 9 is a perspective view showing the assembly after the screw thread processing step being processed according to the present disclosure;

FIG. 10 is a side cross sectional view after the screw hole processing step being processed according to the present disclosure;

FIG. 11 is a side cross sectional view after the penetrated hole processing step being processed according to the present disclosure;

FIG. 12 is a perspective exploded view showing the water-cooling plate according to the present disclosure;

FIG. 13 is a side cross sectional view showing the water-cooling plate according to the present disclosure;

FIG. 14 is a side cross sectional view showing the substrate being milled before the forming step according to the present disclosure;

FIG. 15 is a side cross sectional view showing the substrate while the preparing step being processed according to another embodiment of the present disclosure; and

FIG. 16 is a side cross sectional view showing the substrate after the planing step being processed according to another embodiment of the present disclosure.

### DETAILED DESCRIPTION

It is to be understood that the terms for indicating positions and the location relation, for example “front”, “rear”, “left”, “right”, “front end”, “rear end”, “distal end”, “vertical”, “horizontal”, “top end” and “bottom end”, are based on the positions and the location relation disclosed in the drawings, and only used for disclosing the present disclosure and not used for indicating or implying the specified location of the device or the components or the specified structure and operation in certain location, thus the present disclosure is not intended to be limiting.

The technical contents of this disclosure will become apparent with the detailed description of embodiments accompanied with the illustration of related drawings as follows. It is intended that the embodiments and drawings disclosed herein are to be considered illustrative rather than restrictive.

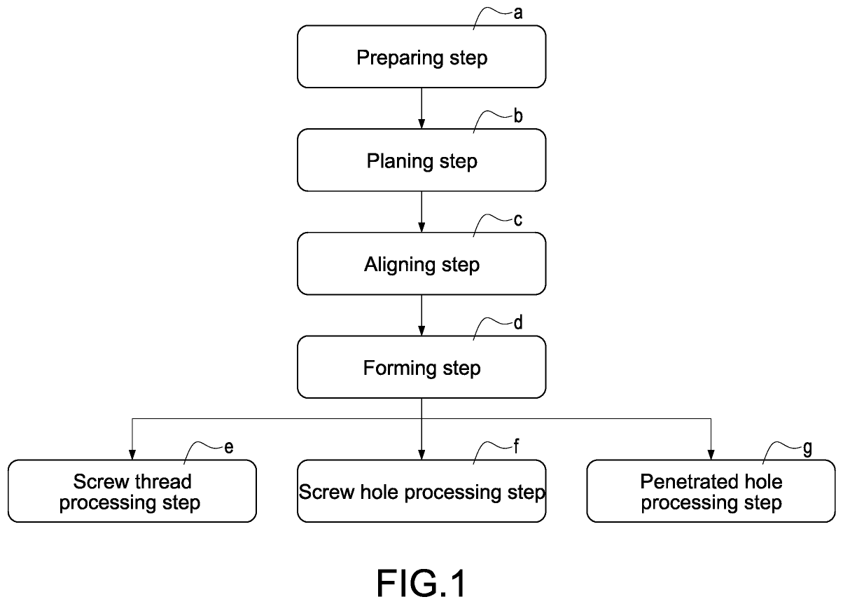

The present disclosure provides a manufacturing method of a water-cooling plate seat. Please refer to FIG. 1, the manufacturing method of the water-cooling plate seat mainly includes a preparing step a, a planing step b, and a forming step c.

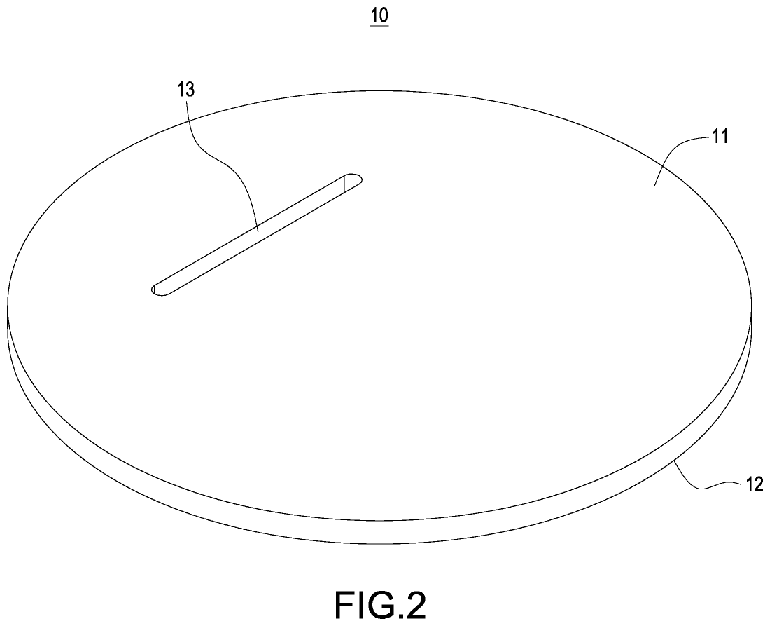

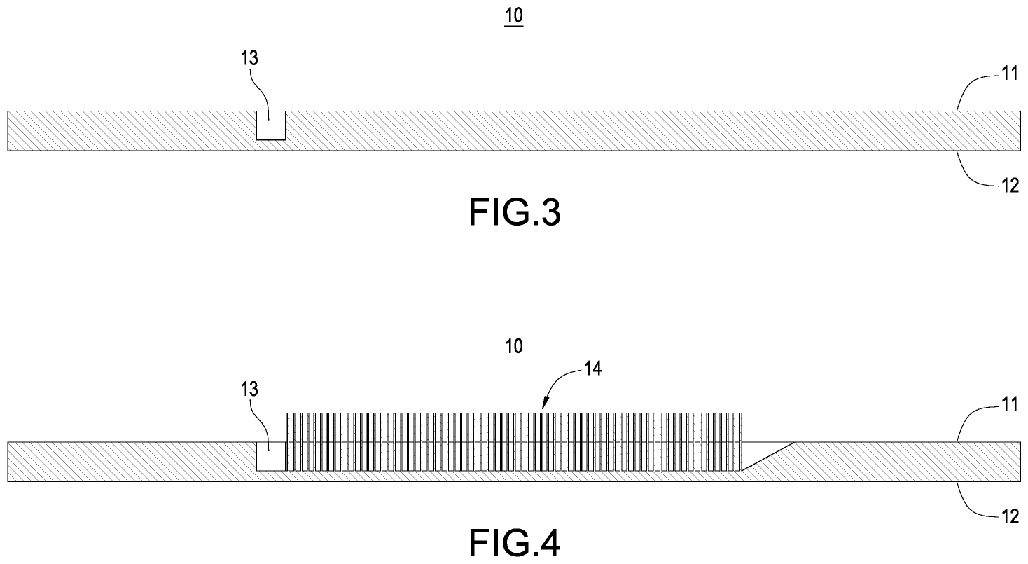

Please refer to FIG. 2 and FIG. 3. In the preparing step a, a substrate 10 is provided. In some embodiments, the substrate 10 is a round plate having a desirable thermal conductivity, here is not intended to be limiting. For example, the substrate 10 is a plate member in a rectangular shape or other geometrical shapes. The substrate 10 has a top surface 11 and a bottom surface 12 opposite to the top surface 11. In some embodiments, the top surface 11 of the substrate 10 has a groove 13. The groove 13 does not penetrate the substrate 10, in other words the groove 13 is not extended to the bottom surface 12 of the substrate 10. In other embodiments, the substrate 10 does not have the groove 13. The groove 13 is formed by a milling or a punching process, or casted with the substrate 10 to be formed in one piece or directly formed by an injection molding manner, here is not intended to be limiting.

In the planing step b, a plurality of fins 14 is formed on the substrate 10 by a planing process, thus each of the fins 14 and the substrate 10 are formed in one piece, in other words each of the fins 14 is defined as a skived fin. Please refer to FIG. 4, in some embodiments, the planing step b is to use a planing process to make the plurality of fins 14 be formed on the top surface 11 of the substrate 10 by utilizing a blade sequentially planing from one side of the groove 13. As such, each of the fins 14 is directly formed on the substrate 10, and a soldering operation requiring a soldering material or a flux is avoided, thus a problem of increasing the thermal resistance because different materials existing on the seat is prevented. Each of the fins 14 protrudes from the top surface 11 and is parallelly arranged with the others. The fins 14 are located at one side of the groove 13 and sequentially distanced away from the groove 13.

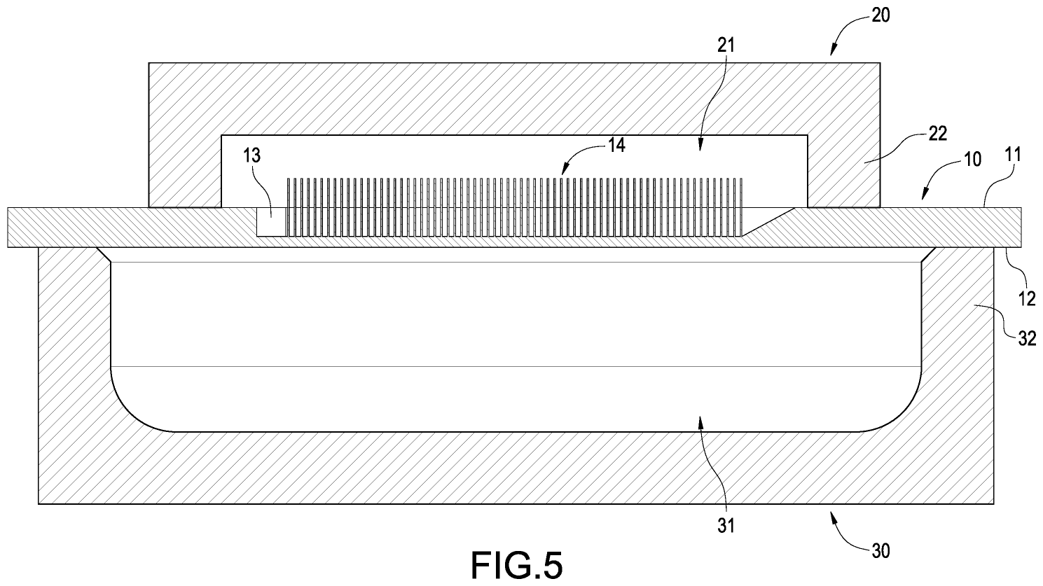

Please refer to FIG. 5, an aligning step c is further included between the planing step b and the forming step d. In the aligning step c, a top mold 20 and a bottom mold 30 are provided. The top mold 20 has a top recess 21 and a top supporting part 22 surrounding the top recess 21. The bottom mold 30 has a bottom recess 31 and a bottom supporting part 32 surrounding the bottom recess 31. The top supporting part 22 abuts against the top surface 11 to make each of the fins 14 be accommodated in the top recess 21. The bottom supporting part 32 abuts against the bottom surface 12 to make the top mold 20 be arranged corresponding to the location of the bottom recess 31, thus the forming step d is easily to be process.

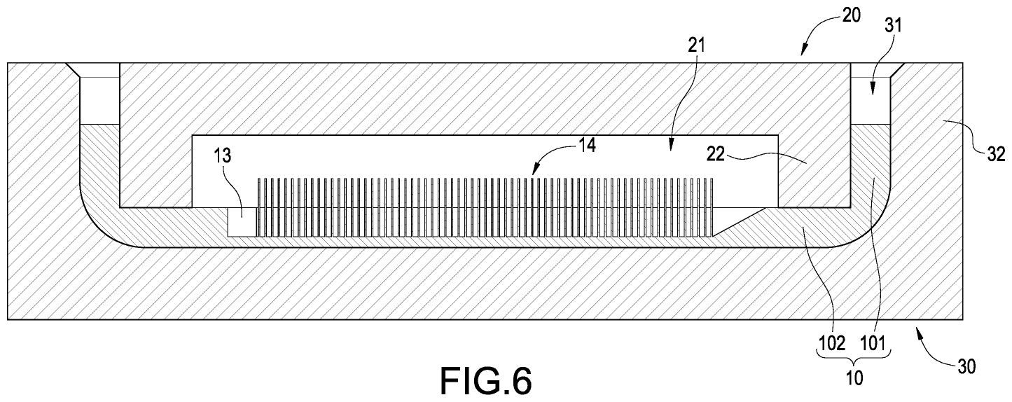

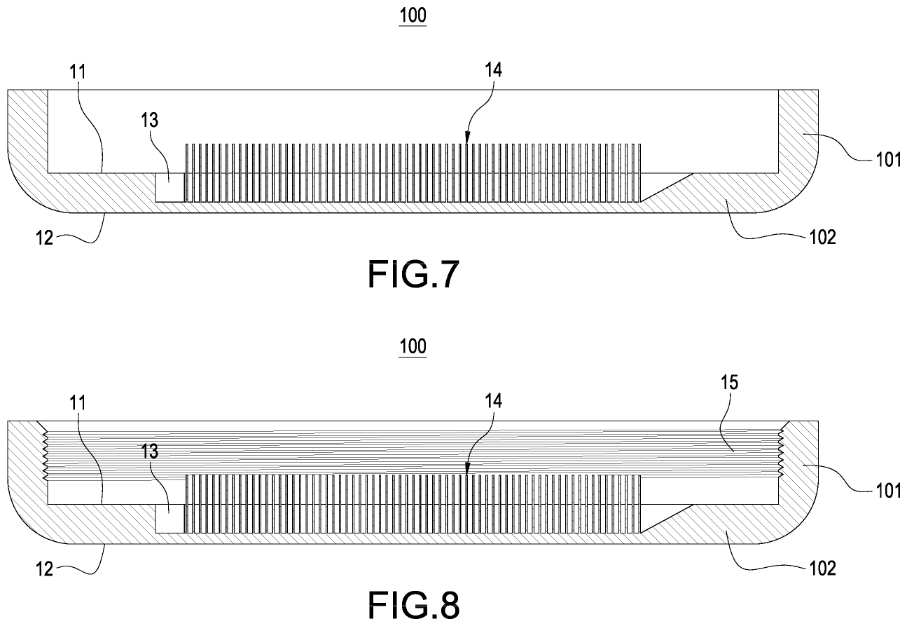

Please refer to FIG. 6 and FIG. 7, the forming step d is provided to the top mold 20 and the bottom mold 30 in the aligning step c. The top mold 20 is engaged with the bottom mold 30 to make the top mold 20 be accommodated in the bottom recess 31, thus the substrate 10 is bent to form a surrounding wall 101 and a bottom plate 102. In some embodiments, the engaging manner disclosed in the forming step d may be a punching, a squeezing or a bending process, here is not intended to be limiting. The groove 13 and each of the fins 14 are located on the top surface 11 of the bottom plate 102. The surrounding wall 101 protrudes from the top surface 11 of the bottom plate 102 and surrounds at a periphery of each of the fins 14. In some embodiments, the surrounding wall 101 is higher than each of the fins 14, in other words a distance between a top end of the surrounding wall 101 and the top surface 11 is greater than a distance between a top end of each of the fins 14 and the top surface 11, here is not intended to be limiting.

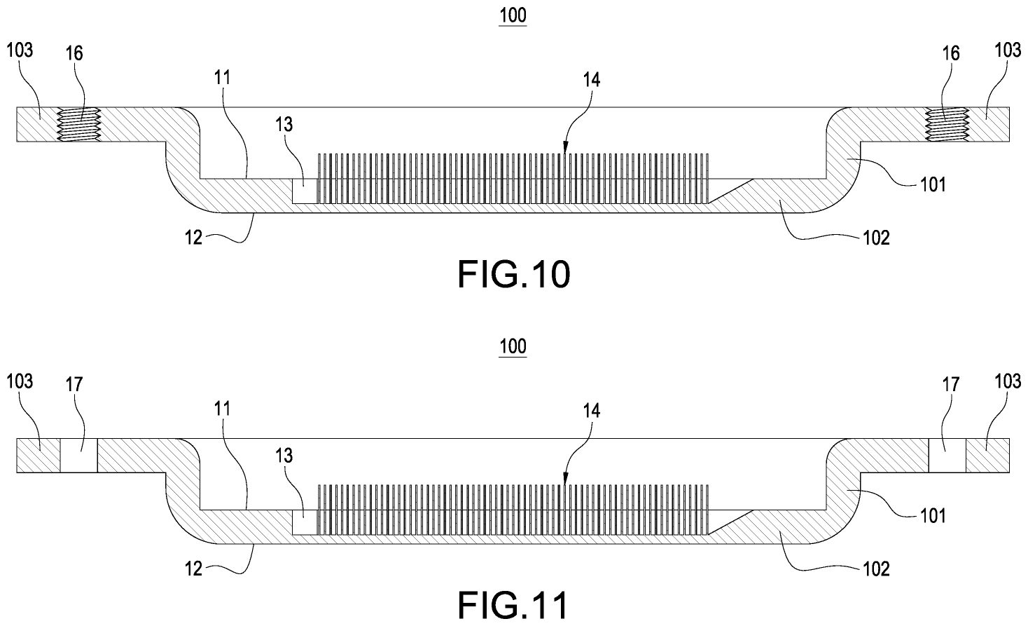

In some embodiments, the surrounding wall 101 formed by the substrate 10 being bent during the formation does not exceed the bottom mold 30, as shown in FIG. 6. In some embodiments, the substrate 10 is bent to form the surrounding wall 101, the bottom plate 102 and a combination plate 103 by slightly adjusting the structure of the top mold 20 and the bottom mold 30. The groove 13 and each of the fins 14 are also located on the top surface 11 of the bottom plate 102, the surrounding wall 101 is connected between the combination plate 103 and the bottom plate 12, and the combination plate 103 and the bottom plate 102 are parallelly arranged. FIG. 10 and FIG. 11 disclose cross sectional views of the seat.

Accordingly, after the seat of the present disclosure is processed with the forming step d, the surrounding wall 101 or the surrounding wall 101 and the combination plate 103 makes the seat and a top cover of the water-cooling plate be combined and fastened by a further processing step. The soldering operation requiring the soldering material or the flux is avoided, thus a problem of increasing the thermal resistance because different materials existing on the seat is prevented. The aforesaid further processing step is categorized to a screw thread processing step e, a screw hole processing step f and a penetrated hole processing step g, which may be selectively processed according to different needs. Details are provided as follows.

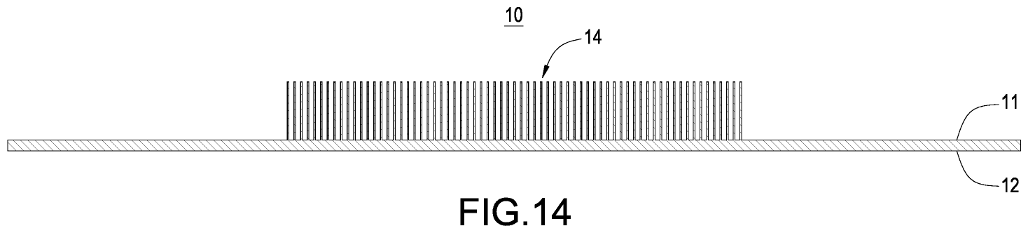

Please refer to FIG. 14, after the substrate 10 is processed with the planing step b to make each of the fins 14 be formed, the substrate 10 is milled by a lathe, thus the top surface 11 of the substrate 10 is aligned with a bottom surface of the groove 13, and then the aligning step c and the forming step d are processed. Accordingly, after the water-cooling plate seat absorbs heat, the heat absorbed by the substrate 10 is efficiently transferred to and collected by each of the fins 14 to make a heat dissipating operation be facilitated. If the top surface 11 of the substrate 10 is not milled to be aligned with the bottom surface of the groove 13, a part of the heat may be accumulated on the top surface 11 of the substrate 10, and the heat dissipating efficiency is affected.

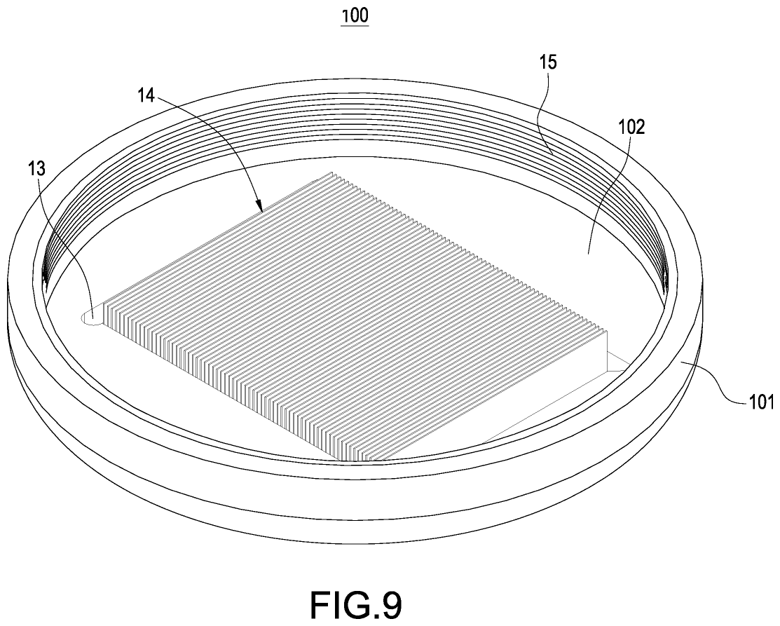

Please refer to FIG. 8 and FIG. 9, the screw thread processing step e is processed after the forming step d, an inner screw thread 15 is mechanically or manually formed at an inner side of the surrounding wall 101. As such, the inner screw thread 15 of the surrounding wall 101 and the top cover of the water-cooling plate are screwed and fastened. As such, a situation of the water-cooling plate having different materials due to the existence of the soldering material or the flux required by the soldering operation is avoided, and problems of increasing the thermal resistance and affecting the heat dissipating efficiency are prevented.

Please refer to FIG. 10, the screw hole processing step f is processed after the forming step d, the combination plate 103 is mechanically or manually processed (for example: drilling, electrical discharge, ultrasonic wave or milling) to form a plurality of screw holes 16. As such, a plurality of screw bolts is utilized to pass the top cover of the water-cooling plate and screwed and fastened with each of the screw holes 16 of the combination plate 103. As such, a situation of the water-cooling plate having different materials due to the existence of the soldering material or the flux required by the soldering operation is avoided, and problems of increasing the thermal resistance and affecting the heat dissipating efficiency are prevented.

Please refer to FIG. 11, the penetrated hole processing step g is processed after the forming step d, the combination plate 103 is mechanically or manually processed (for example: drilling, electrical discharging, ultrasonic wave or milling) to form a plurality of penetrated holes 17. As such, a plurality of screw bolts is utilized to pass the top cover of the water-cooling plate and screwed and fastened with each of the penetrated holes 17 of the combination plate 103. As such, a situation of the water-cooling plate having different materials due to the existence of the soldering material or the flux required by the soldering operation is avoided, and problems of increasing the thermal resistance and affecting the heat dissipating efficiency are prevented.

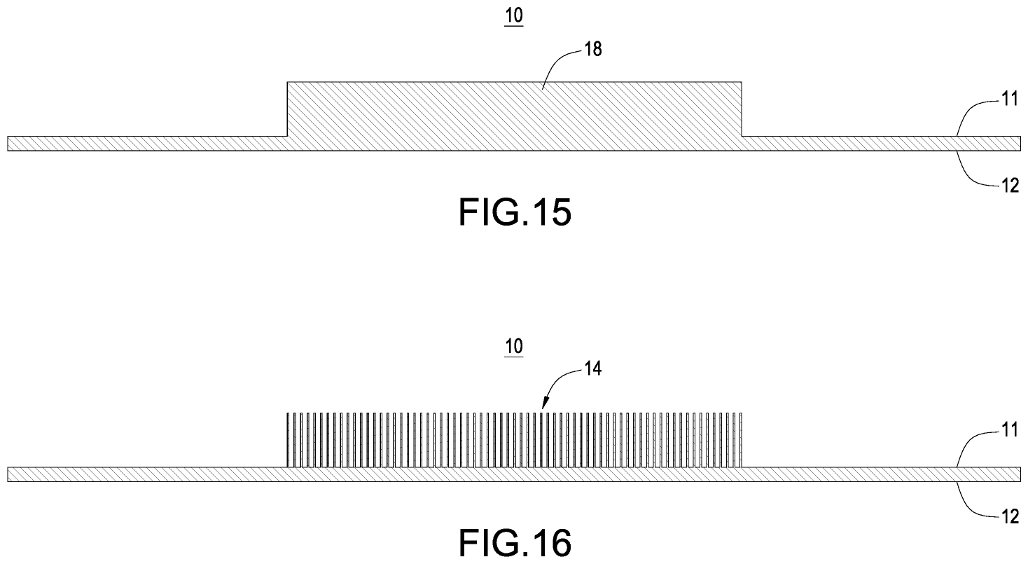

Please refer to FIG. 15, which discloses another embodiment of the present invention, a main difference is that the substrate 10 is not disposed with the groove 13 in the preparing step a. A protrusion 18 is disposed on the top surface 11 of the substrate 10. The protrusion 18 is formed by utilizing a lathe to mill the substrate 10, or the protrusion 18 and the substrate 10 are casted in on piece, here is not intended to be limiting. In some embodiments, in the planing step b, a planing operation is processed to the protrusion 18 to make each of the fins 14 be formed, thus the main structure of the finished water-cooling plate seat is the same as that of the previous embodiment, but the thickness of the substrate 10 disclosed in the another embodiment and the previous embodiment is different, in other words the substrate 10 of the another embodiment is thicker than that of the previous embodiment, thus the forming step d is easier to be processed.

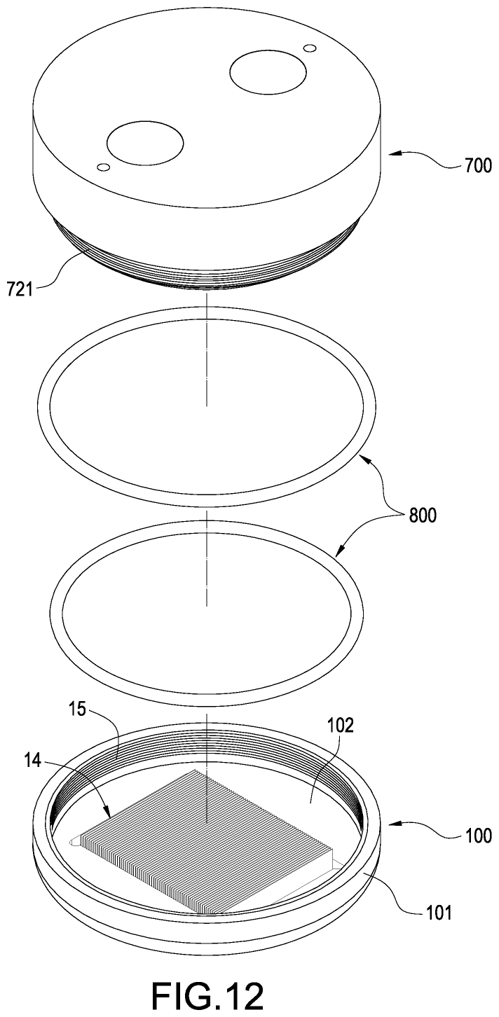

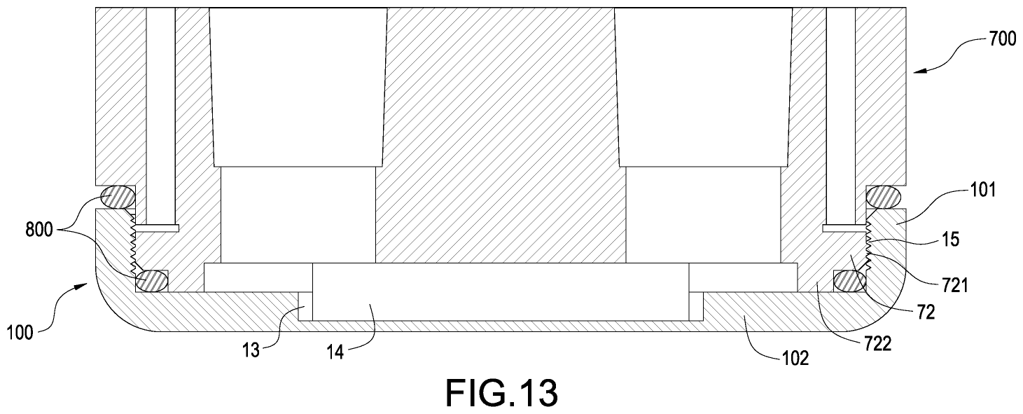

Please refer to FIG. 9, FIG. 12 and FIG. 13, the present disclosure also provides a water-cooling plate. The water-cooling plate mainly a seat 100 and a top cover 700 which are formed in one piece.

In some embodiments, the seat 100 is manufactured by the aforesaid manufacturing method of the water-cooling plate seat working with the screw thread processing step e, in other words the seat 100 includes the bottom plate 102, the surrounding wall 101, the groove 13 and the plurality of fins 14 as shown in FIG. 9. The bottom plate 102 is processed with a planing process to form each of the fins 14, and then the bottom plate 102 is processed with a forming operation to be bent to form the surrounding wall 101. The surrounding wall 101 surrounds and protrudes out of each of the fins 14. An inner side of the surrounding wall 101 is processed to be formed with the inner screw thread 15.

In some embodiments, the appearance of the top cover 700 is corresponding to the appearance of the seat 100 to be in a round columnar status, and made of the same material of which the seat 100 is made, here is not intended to be limiting. The top cover 700 is correspondingly combined and fastened with the seat 100 and a chamber 71 is jointly formed by the top cover 700 and the seat 100. Each of the fins 14 is accommodated in the chamber 71. The top cover 700 has a combination part 72. The combination part 72 is in a round columnar status and protruded and extended from a bottom end of the top cover 700, and an outer diameter of the combination part 72 is smaller than an outer diameter of the top cover 700, here is not intended to be limiting. The combination part 72 of the top cover 700 has an outer screw thread 721. The outer screw thread 721 of the top cover 700 is correspondingly screwed and fastened with the inner screw thread 15 of the surrounding wall 101, in other words the combination part 72 is located at an inner side of the surrounding wall 101 to make the outer screw thread 721 be screwed with the inner screw thread 15, thus the top cover 700 is locked and fastened on the seat 100.

Accordingly, the inner screw thread 15 of the surrounding wall 101 of the seat 10 is screwed with the outer screw thread 721 of the top cover 700 of the water-cooling plate for the purpose of combining and fastening. A situation of the water-cooling plate having different materials due to the existence of the soldering material or the flux required by the soldering operation is avoided, and problems of increasing the thermal resistance and affecting the heat dissipating efficiency are prevented

Please refer to FIG. 12 and FIG. 13, the water-cooling plate of the present disclosure further includes at least one rubber ring 800. In some embodiments, there are two rubber rings 800, here is not intended to be limiting. The amount of the rubber ring 800 may be one or equal to or more than three according to actual needs. The combination part 72 of the top cover 700 has a flange 722. The flange 722 is protruded and extended from a bottom end of the combination part 72, an outer diameter of the flange 722 is smaller than an outer diameter of the combination part 72, here is not intended to be limiting. One of the rubber rings 800 sheathes an outer edge of the combination part 72 and is elastically clamped between the top cover 700 and the seat 100. The other rubber ring 800 sheathes an outer edge of the flange 722 of the combination part 72 and is elastically clamped between the top cover 700 and the seat 100, thus the water-cooling plate is ensured to be provided with a sealing effect and a situation of liquid leaking is prevented.

It is to be understood that the combining and fastening manner of the top cover 700 and the seat 100 is not limited to the aforesaid manner. In other embodiments, when the seat 100 is manufactured by the aforesaid manufacturing method of the water-cooling plate seat working with the screw hole processing step for the penetrated hole processing step g, the water-cooling plate of the present disclosure further includes a plurality of screw bolts (not shown in figures). In some embodiments, the substrate 10 is bent to form a combination plate 103 parallel to the bottom plate 102 during the forming process. The surrounding wall 101 is connected between the combination wall 103 and the bottom plate 102. Each of the screw bolts passes one of the top cover 700 and the combination wall 103 and then be alternatively screwed with one of the combination wall 103 and the top cover 700, thus the top cover 700 is fastened on the seat 100 via each of the screw bolts.

Substantially speaking, if the seat 100 is formed with the plurality screw holes 16 in the screw hole processing step f, the top cover 700 is formed with a plurality of fastening holes (not shown in figures) corresponding to each of the screw holes 16. Each of the screw bolts passes each of the fastening holes of the top cover 700 and screwed and fastened with each of the screw holes 16 of the combination plate 103. If the seat 100 is formed with the plurality penetrated holes 17 in the penetrated hole processing step g, the top cover 700 is formed with a plurality of screw thread holes (not shown in figures) corresponding to each of the penetrated holes 17. Each of the screw bolts passes each of the penetrated holes 17 of the combination plate 103 and screwed and fastened with each of the screw thread holes of the top cover 700.

According to the manufacturing method of the water-cooling plate seat of the present disclosure, the plurality of fins 14 are directly formed on the substrate 10 in the planing step b. The soldering operation requiring the soldering material or the flux is avoided, thus a problem of increasing the thermal resistance is prevented. The substrate 10 is bent to form the surrounding wall 101 in the forming step d, thus subsequent processes and the assembly or disassembly with the top cover 700 are facilitated. The soldering operation requiring the soldering material or the flux is avoided, thus a problem of increasing the thermal resistance is prevented.

According to the water-cooling plate of the present disclosure, each of the fins 14 and the seat 100 are formed in one piece, the top cover 700 and the seat 100 are correspondingly combined and fastened, and the combination of the fins 14 and the seat 100 or the combination of the top cover 700 and the seat 100 does not required a soldering operation, thus the soldering material or the flux required by the soldering operation are saved, and problems of increasing the thermal resistance and affecting the heat dissipating efficiency are prevented.

While this disclosure has been described by means of specific embodiments, numerous modifications and variations could be made thereto by those skilled in the art without departing from the scope and spirit of this disclosure set forth in the claims.

What is claimed is:

1. A manufacturing method of a water-cooling plate seat, the manufacturing method comprising:
a preparing step, comprising providing a substrate, wherein the substrate comprises a top surface and a bottom surface opposite to each other;
a planing step, comprising planing and processing the substrate to form a plurality of fins, wherein each of the fins protrudes from the top surface; and
a forming step, comprising providing a top mold and a bottom mold, engaging the top mold with the bottom mold to bend the substrate to form a surrounding wall, wherein the surrounding wall protrudes from the top surface and surrounds each of the fins.

2. The manufacturing method according to claim 1, wherein in the preparing step, the substrate comprises a groove defining on the top surface thereof, the planing step comprises planing and processing the top surface from one side of the groove to sequentially form each of the fins.

3. The manufacturing method according to claim 2, wherein after each of the fins is formed, the manufacturing method further comprises milling the substrate to align the top surface with a bottom surface of the groove, and then performing the forming step.

4. The manufacturing method according to claim 1, wherein in the preparing step, the substrate comprises a protrusion located on the top surface, and the planing step comprises planing and processing the protrusion to form each of the fins.

5. The manufacturing method according to claim 1, further comprising an aligning step between the planing step and the forming step, wherein the aligning step comprises providing a top mold and a bottom mold, the top mold comprises a top recess and a top supporting part surrounding the top recess, the bottom mold comprises a bottom recess and a bottom supporting part surrounding the bottom recess, the aligning step further comprises making the top supporting part abut against the top surface to accommodate each of the fins in the top recess, and making the bottom supporting part abut against the bottom surface to arranging the top mold corresponding to the bottom recess.

6. The manufacturing method according to claim 1, further comprising a screw thread processing step, wherein the screw thread processing step comprises forming an inner screw thread on an inner side of the surrounding wall after the forming step is finished.

7. The manufacturing method according to claim 1, wherein the forming step further comprises bending the substrate to form a combination plate and a bottom plate, the groove and each of the fins are located on the bottom plate, and the surrounding wall is connected between the combination wall and the bottom plate.

8. The manufacturing method according to claim 7, further comprising a screw hole processing step, wherein the screw hole processing step comprises processing the combination plate to form a plurality of screw holes after the forming step is finished.

9. The manufacturing method according to claim 7, further comprising a penetrated hole processing step, wherein the penetrated hole processing step comprises processing the combination plate to form a plurality of penetrated holes after the forming step is finished.

10. A water-cooling plate, comprising:
a seat, in one piece form and comprising a surrounding wall, a bottom plate and a plurality of fins, wherein the bottom plate is processed with a planing operation to form each of the fins, the bottom plate is processed with a forming operation to be bent to form the surrounding wall, and the surrounding wall surrounds and protrudes from each of the fins; and
a top cover, correspondingly combined and fastened with the seat to define a chamber, and each of the fins is accommodated in the chamber.

11. The water-cooling plate according to claim 10, wherein the surrounding wall comprises an inner screw thread, the top cover comprises an outer screw thread, and the outer screw thread is correspondingly screwed with the inner screw thread.

12. The water-cooling plate according to claim 10, further comprising a plurality of screw bolts, the substrate is bent to form a combination plate, the surrounding wall is connected between the combination plate and the bottom plate, and each of the screw bolts passes through one of the top cover and the combination wall to be screwed with another one of the combination wall and the top cover.

13. The water-cooling plate according to claim 10, further comprising a rubber ring, the top cover comprises a combination part, and the rubber ring sheathes the combination part and is elastically clamped between the top cover and the seat.
